(19) United States
(12) Patent Application Publication
(10) Pub. No.: US 2017/0018306 A1
(43) Pub. Date: Jan. 19, 2017

(54) Resistive Random Access Memory And Writing Operation Method Thereof

(71) Applicant: FUDAN UNIVERSITY, Shanghai (CN)

(72) Inventors: Yinyin Lin, Shanghai (CN); Ying Meng, Shanghai (CN)

(21) Appl. No.: 15/121,101

(22) PCT Filed: Sep. 17, 2014
(86) PCT No.: PCT/CN2014/086688

§ 371 Date: Aug. 24, 2016

(30) Foreign Application Priority Data
Feb. 28, 2014 (CN) 201410072234.7

(51) Int. Cl. G11C 13/00

(52) U.S. Cl. CPC G11C 13/0069; G11C 13/0097; G11C 13/0064; G11C 2013/0092

(57) ABSTRACT

The invention provides a resistive random access memory and a writing operation method thereof, and pertains to the technical field of resistive random access memory (ReRAM). The resistive random access memory comprises a writing operation signal generation module which is at least used for generating electrical signal(s) hazing gradually reducing voltages as set operation signals; in a Set operation method of the writing operation method, electrical signal(s) hazing gradually reducing voltages are biased, as Set operation signals, onto a selected memory unit in the resistive random access memory. The Set operation method can improve storage performances of ReRAM in terms of endurance, data retention and high resistance/low resistance window, etc.

### FIELD OF THE INVENTION

The invention pertains to the technical field of resistive random access memory (ReRAM), and relates to a ReRAM and a writing operation method thereof which use an electrical signal having a step-reducing voltage to perform a Set operation.

### BACKGROUND OF THE INVENTION

ReRAM has such characteristics of non-volatile, low cost, high density, the ability of breaking through restraints of process technology generation development and so on. Due to these characteristics, researches have been widely made on ReRAM, and ReRAM is considered as one of the semiconductor storage technologies that can replace flash memory.

In each memory unit of ReRAM, a biased electrical signal is applied so that a reversible conversion is made for the storage medium between a high resistance state (HRS) and a low resistance state (LRS) so as to realize a storing function, wherein the conversion from HRS to LRS is typically defined as “Set” operation, and the conversion from LRS to HRS is typically defined as “Reset” operation.

It can be seen from the article “Atomic structure of conducting nanofilaments in TiO2 resistive switching memory” published in the magazine “Nature Nanotechnology” by Deok-Hwang Kwo, et al. that during the Set operation, the storage medium will form a plurality of conductive filaments (CFs) by for example oxygen vacancy movement, thus realizing a low resistance conduction between a top electrode (TE) and a bottom electrode (BE) of the storage medium; moreover, during the Reset operation, the CFs are cut off or eliminated so as to realize a high resistance conversion.

U.S. Pat. No. 7,920,405B2, entitled “CIRCUITS AND METHODS FOR ADAPTIVE WRITE BIAS DRIVING OF RESISTIVE NON-VOLATILE MEMORY DEVICES” and filed by Sang-beom Kang et at., discloses a Set operation method for ReRAM to realize a writing operation, as shown in FIG. 1, which is a schematic view of a Set operation signal of ReRAM according to an embodiment of the prior art.

US Patent Publication No. US2012/0075908A1, entitled “RESISTIVE RANDOM ACCESS MEMORY AND VERIFYING METHOD THEREOF” and filed by Chih-He Lin et at., discloses another Set operation method for ReRAM to realize a writing operation, as shown in FIG. 2, which is a schematic view of a Set operation signal of ReRAM according to another embodiment of the prior art.

It can be seen that all of the above proposed Set operation methods for ReRAM use an electrical signal having a step-increasing voltage to perform the Set operation.

### SUMMARY OF THE INVENTION

The objective of the invention is to improve storage performance of ReRAM by changing the Set operation manner.

In order to realize the above or other objectives, the invention provides the following technical solution.

According to an aspect of the invention, a resistive random access memory is provided, comprising:

a writing operation signal generation module which is at least used for generating electrical signal(s) hazing gradually reducing voltages as a Set operation signal.

In an embodiment, the electrical signal(s) hazing gradually reducing voltages can be electrical signal(s) hazing step-reducing voltages.

In the above described embodiment, the electrical signal(s) hazing step-reducing voltages can be an electrical signal hazing continuously step-reducing voltages.

In the previous embodiment, the electrical signal(s) hazing step-reducing voltages can be also step voltage pulse signals having step-reducing voltages.

In further another embodiment, the electrical signal(s) hazing gradually reducing voltages are an electrical signal hazing continuously gradually reducing voltages.

In the resistive random access memory according to a preferred embodiment of the invention, the resistive random access memory further comprises:

a dynamic current detection module which is at least used for dynamically detecting a current flowing through a memory unit of the resistive random access memory which is biased the Set operation signal, so as to determine whether the Set operation was successful; and

a control logic module which is configured to receive a feedback signal from the dynamic current detection module in case that the dynamic current detection module determined the Set operation was successful, and based on the feedback signal, to enable the writing operation signal generation module to terminate generating the Set operation signal.

Specifically, the resistive random access memory further comprises:

a polarity selection module for controlling the polarity that is biased on the memory unit by the Set operation signal and/or a Reset operation signal; and

a selection module for selecting a corresponding memory unit from a memory array of the resistive random access memory according to an address signal.

In the resistive random access memory according to another embodiment of the invention, the writing operation signal generation module is further used for generating electrical signal(s) hazing gradually increasing voltages as a Reset operation signals.

Preferably, the electrical signal(s) hazing gradually increasing voltages are step voltage pulse signal(s) hazing step-increasing voltages.

In any of the above described embodiments, optionally, the writing operation signal generation module is further used for generating a verifying signal so as to verify whether the Set operation and/or Reset operation was successful. Of course, in this situation, the dynamic current detection module may also generate a feedback (FB) signal indicating whether the Set operation/Reset operation was successful.

According to another aspect of the invention, a writing operation method for a resistive random access memory is provided, wherein in a Set operation method of the writing operation method, electrical signal(s) hazing gradually reducing voltages is biased, as Set operation signals, onto a selected memory unit in the resistive random access memory.

In an embodiment, the electrical signal(s) hazing gradually reducing voltages are electrical signal hazing step-reducing voltages.

In the above described embodiment, the electrical signal(s) hazing step-reducing voltages are an electrical signal hazing continuously step-reducing voltages.

In the previous embodiment, the electrical signal(s) hazing step-reducing voltages are step voltage pulse signal(s) hazing step-reducing voltages.

In further another embodiment, the electrical signal(s) hazing gradually reducing voltages are an electrical signal hazing continuously gradually reducing voltages.

In the writing operation method according to a preferred embodiment of the invention, the Set operation method further comprises:

dynamically detecting a current flowing through a memory unit of the resistive random access memory which is biased the Set operation signal, so as to determine whether the Set operation was successful;

if it is determined that the Set operation was successful, the Set operation signal is terminated; and if it is determined that the Set operation was not successful, the voltage of the Set operation signal will go on reducing.

In the writing operation method according to further another embodiment of the invention, when the electrical signal(s) hazing step-reducing voltages are step voltage pulse signals, after each time a voltage pulse excitation is applied, a verifying signal is biased so as to verify whether the Set operation was successful.

In any of the above described embodiments, in a Reset operation method of the writing operation method, electrical signal(s) hazing gradually increasing voltages are biased, as a Reset operation signals, onto a selected memory unit in the resistive random access memory.

Optionally, the electrical signal(s) hazing gradually increasing voltages can be electrical signal(s) hazing step-increasing voltages.

Optionally, the electrical signal(s) hazing step-increasing voltages can be an electrical signal hazing continuously step-increasing voltages.

Optionally, the electrical signal(s) hazing step-increasing voltages can be step voltage pulse signal(s) hazing step-increasing voltages.

In any of the above described embodiments, optionally, after each time a voltage pulse excitation is applied, a verifying signal is biased so as to verify whether the Reset operation was successful.

In any of the above described embodiments, optionally, the Reset operation method further comprises:

dynamically detecting a current flowing through a memory unit of the resistive random access memory which is biased the Reset operation signal, so as to determine whether the Reset operation was successful;

if it is determined that the Reset operation was successful, the Reset operation signal is terminated; and if it is determined that the Reset operation was not successful, the voltage of the Reset operation signal will go on increasing.

The invention brings about the following technical effects: the shape of CFs formed in the storage medium can be changed by using an electrical signal having a gradually reducing voltage as a Set operation signal to perform a Set operation; in this way, the storage performance of ReRAM can be improved in terms of endurance, data retention and high resistance/low resistance window, etc.

### BRIEF DESCRIPTION OF THE ACCOMPANYING DRAWINGS

The above and other objectives and advantages of the invention will become thoroughly clear from the following detailed description in connection with the accompanying drawings, wherein identical or similar elements are denoted by identical reference numerals.

FIG. 1 is a schematic view of a Set operation signal of a ReRAM according to an embodiment in the prior art.

FIG. 2 is a schematic view of a Set operation signal of a ReRAM according to another embodiment in the prior art.

FIG. 3 is a schematic view of module structure of a ReRAM according to an embodiment of the invention.

FIG. 4 is a schematic view of a Set operation signal according to a first embodiment of the invention.

FIG. 5 is a schematic view of a Reset operation signal according to a first embodiment of the invention.

FIG. 6 is a schematic view of a Set operation signal according to a second embodiment of the invention.

FIG. 7 is a schematic view of a Reset operation signal according to a second embodiment of the invention.

FIG. 8 is a schematic view of a Set operation signal according to a third embodiment of the invention.

FIG. 9 is a schematic view of a Set operation signal according to a fourth embodiment of the invention.

FIG. 10 is a schematic view of a method flowchart of a Set operation according to an embodiment of the invention.

FIG. 11 is a schematic view of the formation of conductive filaments in ReRAM.

FIG. 12 is a schematic view of a method flowchart of a Set operation according to another embodiment of the invention.

FIG. 13 is a schematic view of a method flowchart of a Reset operation according to another embodiment of the invention.

### DETAILED DESCRIPTION OF THE EMBODIMENTS

Some of the many possible embodiments of the invention will be described below with the purpose of providing a basic understanding of the invention rather than identifying key elements or crucial elements of the invention or limiting the scope of protection. It can be easily understood that according to the technical solutions of the invention, those skilled in the art can propose other implementations that can be replaced with each other without departing from the true spirit of the invention. Therefore, the following specific embodiments and drawings are merely exemplary description of the technical solutions of the invention, and should not be considered as the entirety of the invention or as limiting or restricting the technical solutions of the invention.

For a clear and brief explanation, in the following description, not all the components shown in the accompanying drawings are described in detail. The drawings show many components that can be completely realized for completing the invention by those skilled in the art. For those skilled in the art, the operations of many components are familiar and obvious.

In the following description, a high resistance state of the memory unit in ReRAM is defined as data “0”, and correspondingly, a low resistance state of the memory unit in ReRAM is defined as data “1”; a Set operation is a writing operation in which data “0” is written to be “1”, and a Reset operation is a writing operation in which data “1” is written to be “0”.

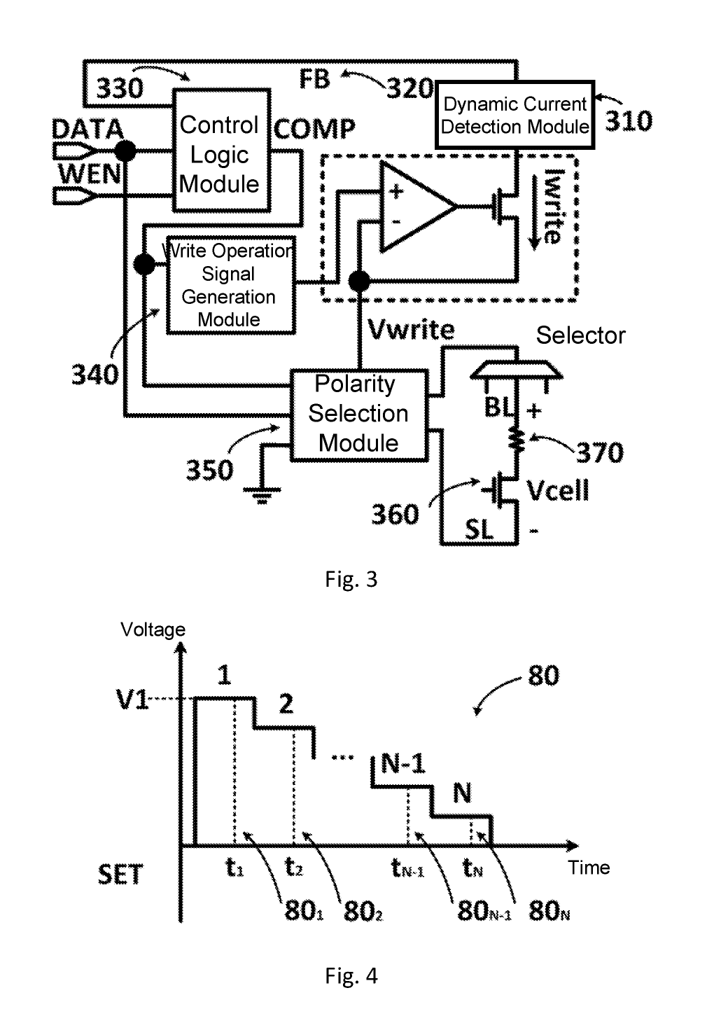

FIG. 3 is a schematic view of module structure of a ReRAM according to an embodiment of the invention. As shown in FIG. 3, the ReRAM also comprises a plurality of memory units 370, for which a conversion between a high resistance state and a low resistance state can be realized repeatedly. The plurality of memory units 370 can form a memory array by being arranged in rows and columns. In the embodiment of the invention, for a concise and clear description, only the Set/Reset operations performed by one of the memory units 370 that has been selected is illustrated. Similarly, this ReRAM comprises a selection module that is used for selecting a corresponding memory unit from the memory array of according to an address signal. For example, the selection module can be a row selector, a MOS gate tube 360 or the like, wherein BL represents a bit line in the memory array, and SL represents a source line in the memory array.

In this embodiment, the ReRAM is further provided with a writing operation signal generation module 340 which can generate a Set operation signal and a Reset operation signal, the specific forms of which will be described in detail hereinafter.

In this embodiment, preferably, the ReRAM is further provided with a dynamic current detection module 310 and a control logic module 330; the dynamic current detection module 310 can dynamically detect a write current (I_{write}) flowing through the memory unit 370 at any time so as to determine whether the writing operation (e.g., a Set operation or a Reset operation) was successful. The dynamic current detection module 310 is coupled with the control logic module 330, and sends a feedback (FB) signal 320 to the control logic module 330 in a case where it is determined that the writing operation was successful. Based on this FB signal, the control logic module 330 enables the writing operation signal generation module 340 to terminate generating the Set/Reset operation signal. In this way, by means of a dynamic feedback of current detection, a situation in which redundant Set/Reset excitation is biased onto a memory unit which has successfully performed the Set/Reset operation is avoided, which is not only advantageous for increasing the speed of Set/Reset operation, but also is advantageous for reducing power consumption of Set/Reset operation and improving data retention.

With continued reference to FIG. 3, an input end of the control logic module 330 is input with data signal DATA, i.e., data signal that needs to be written-in. If DATA=0, it means that a Reset operation may be required to be performed; and if DATA=1, it means that a Set operation may be required to be performed. The input end of the control logic module 330 may be also input with a write enable signal WEN. In this example, when WEN=1, a write circuit is enabled to work so as to start the Set or Reset operation. An output end of the control logic module 330 is coupled with the writing operation signal generation module 340 and a polarity selection module 350. The polarity selection module 350 is used for controlling the polarity that is biased on the memory unit 370 by the Set/Reset operation signal. For example, when DATA=1, a write voltage (Vwrite) generated by the writing operation signal generation module 340 is applied onto the memory unit 370 in the BL direction, and this operation direction is Set operation direction; on the contrary, Vwrite is applied onto the memory unit 370 in the SL direction so as to perform Reset operation. The control logic module 330 can also, based on the FB signal, enable the polarity selection module 350 to stop working.

With continued reference to FIG. 3, the signal generated by the writing operation signal generation module 340 is input to a “+” input end (forward direction input end) of an amplifier, and a “−” input end (reverse direction input end) of the amplifier is connected to the polarity selection module 350. For an ideal operational amplifier, the voltage of the forward direction input end is completely equal to the voltage of the reverse direction input end. The operational amplifier and a transistor connected to its output end constitute a negative feedback loop so as to form a write voltage current converter.

Of the signals generated by the writing operation signal generation module 340, at least the Set operation signal has a gradually-reducing voltage. The Set operation signal and the Reset operation signal generated by the writing operation signal generation module 340 will be explained in detail below.

FIG. 4 is a schematic view of a Set operation signal according to a first embodiment of the invention. As shown in FIG. 4, an initial voltage (i.e., the magnitude of voltage initially biased onto the memory unit 370) of the Set operation signal is V₁. In this embodiment, the voltage of Set operation signal is reduced in continuous steps. For example, there can be N steps in total, and the voltage can be V₁ to V_{N} respectively.

The initial voltage V₁ can be set by being chosen within a certain range. Typically, the initial voltage V₁ can be chosen to be smaller than Vₛₑₜ (i.e., the voltage value at which a single pulse can enable the Set operation to be successful). Those skilled in the art can determine the magnitude of V₁ by having Set tests on the plurality of memory units. It should be understood that the specific magnitude of V₁ is not restricted by the embodiments of the invention. The amplitude of voltage step-reducing between steps is not specifically restricted. Therefore, N can be any integer larger than or equal to 2, 0<V_{N}<V₁. In order to improve the efficiency of Set operation, limit values can be set for the magnitudes of N and V_{N}, so as to prevent time from being excessively consumed in case that a certain memory unit has an unsuccessful Set operation.

At each step, it is possible that the Set operation can be successfully realized. As described above, by dynamically monitoring I_{write} using the dynamic current detection module 310, conversion points of resistance can be determined, and the generation of Set operation signal can be terminated. As shown in FIG. 4, t₁, t₂ to t_{N} are possible conversion points of resistance, and at a corresponding time point, the voltage is reduced to zero. Therefore, Set operation signals 80₁, 80₂, . . . , 80_{N-1}, 80_{N} can be formed respectively.

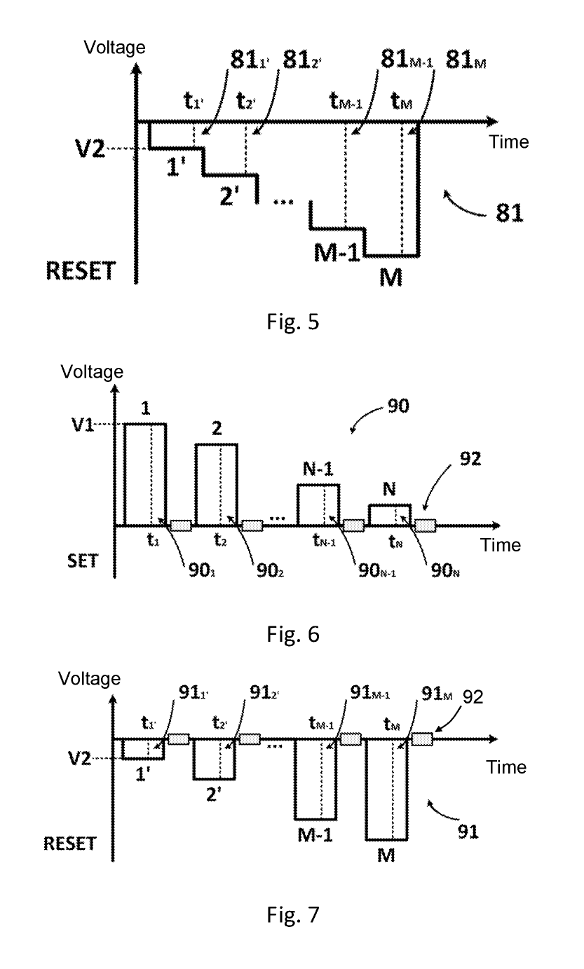

FIG. 5 is a schematic view of a Reset operation signal according to a first embodiment of the invention. As shown in FIG. 5, the initial voltage (i.e., the magnitude of voltage initially biased onto the memory unit 370) of Reset operation signal 81 is V₂. In this embodiment, the voltage of Reset operation signal is increased in continuous steps. For example, there can be M steps in total.

At each step, it is possible that the Reset operation can be successfully realized. As described above, by dynamically monitoring I_{write} using the dynamic current detection module 310, conversion points of resistance can be determined, and the generation of Reset operation signal can be terminated. As shown in FIG. 5, t_{1′}, t_{2′} to t_{M} are possible conversion points of resistance, and at a corresponding time point, the voltage is reduced to zero. Therefore, Reset operation signals 80_{1′}, 80_{2′}, . . . , 80_{M-1}, 80_{M} can be formed respectively.

FIG. 6 is a schematic view of Set operation signal according to a second embodiment of the invention. As shown in FIG. 6, the initial voltage (i.e., the magnitude of voltage initially biased onto the memory unit 370) of Set operation signal 90 is V₁. In this embodiment, the Set operation signals are a series of voltage pulse excitation signals whose pulse heights are descended in steps, thus forming step voltage pulse signals whose voltages are reduced in steps, as shown in the figure. For example, N pulse voltage signals whose voltages are reduced in steps sequentially can be formed, and the pulse voltages can be V₁ to V_{N} respectively.

The initial voltage V₁ can be set by being selected within a certain range. Typically, the initial voltage V₁ can be chosen to be smaller than Vₛₑₜ (i.e., the voltage value at which a single pulse can enable the Set operation to be successful). Those skilled in the art can determine the magnitude of V₁ by having Set tests on the plurality of memory units. It should be understood that the specific magnitude of V₁ is not restricted by the embodiments of the invention. The amplitude of voltage step-reducing between pulses is not specifically restricted. Therefore, N can be any integer larger than or equal to 2, 0<VN<V₁. In order to improve the efficiency of Set operation, limit values can be set for the magnitudes of N and V_{N}, so as to prevent time from being excessively consumed in case that a certain memory unit has an unsuccessful Set operation.

At each step voltage pulse signal, it is possible that the Set operation can be successfully realized. As described above, by dynamically monitoring I_{write} using the dynamic current detection module 310, conversion points of resistance can be determined, and the generation of Set operation signal can be terminated. As shown in FIG. 6, t₁, t₂ to t_{N} are possible conversion points of resistance, and at a corresponding time point, the voltage is reduced to zero rapidly. Therefore, Set operation signals 90₁, 90₂, . . . , 90_{N-1}, 90_{N} that comprise at least one pulse can be formed respectively.

With continued reference to FIG. 6, in this embodiment, after each time a voltage pulse excitation is applied, a verifying signal 92 is biased onto the memory unit 370 so as to determine whether the Set operation was successful. In this way, the success of Set operation can be ensured more precisely.

FIG. 7 is a schematic view of Reset operation signal according to a second embodiment of the invention. As shown in FIG. 7, the initial voltage (i.e., the magnitude of voltage initially biased onto the memory unit 370) of Reset operation signal 91 is V₂. In this embodiment, the Reset operation signals are a series of voltage pulse excitation signals whose pulse heights are ascended in steps, thus forming step voltage pulse signals whose voltages are increased in steps, as shown in the figure. For example, M pulse voltage signals whose voltages are reduced in steps sequentially can be formed.

At each step voltage pulse signal, it is possible that the Reset operation can be successfully realized. As described above, by dynamically monitoring I_{write} using the dynamic current detection module 310, conversion points of resistance can be determined, and the generation of Reset operation signal can be terminated. As shown in FIG. 7, t_{1′}, t_{2′}, . . . t_{M-1}, t_{M} are possible conversion points of resistance, and at a corresponding time point, the voltage is reduced to zero rapidly. Therefore, Reset operation signals 90₁, 90₂, . . . , 90_{N-1}, 90_{N} that comprise at least one pulse can be formed respectively.

With continued reference to FIG. 7, in this embodiment, after each time a voltage pulse excitation is applied, a verifying signal 92 is biased onto the memory unit 370 so as to determine whether the Reset operation was successful. In this way, the success of Reset operation can be ensured more precisely.

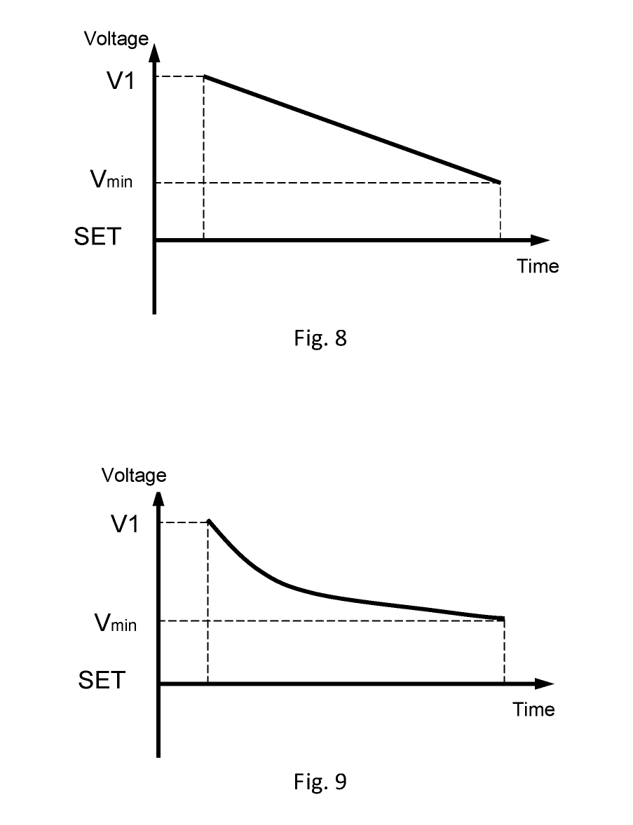

FIG. 8 is a schematic view of a Set operation signal according to a third embodiment of the invention. In this embodiment, Set operation signal hazing gradually-reducing voltages are realized in the form of gradually continuous reduction of voltage. That is, electrical signal hazing gradually and continuously reducing voltages are generated from initial voltage V₁ to voltage Vₘᵢₙ in the form of linear reduction.

FIG. 9 is a schematic view of a Set operation signal according to a fourth embodiment of the invention. In this embodiment, Set operation signal hazing gradually-reducing voltages are realized in the form of gradually continuous reduction of voltage. That is, electrical signal hazing gradually and continuously reducing voltages are generated from initial voltage V₁ to voltage Vₘᵢₙ in the form of arc reduction.

It should be understood that the form of voltage reduction of Set operation signals are not limited to the above described embodiments. Based on the above teaching and enlightenment, those skilled in the art can obtain other equivalent forms of voltage reduction, and can perform Set operations on ReRAM using electrical signals whose voltages are gradually reduced in various forms, which will all fall within the scope of protection of the invention.

Similarly, the forms of voltage increase of Reset operation signal are not limited to the above described embodiments. Those skilled in the art can obtain other equivalent forms of voltage increase based on the above teaching and enlightenment.

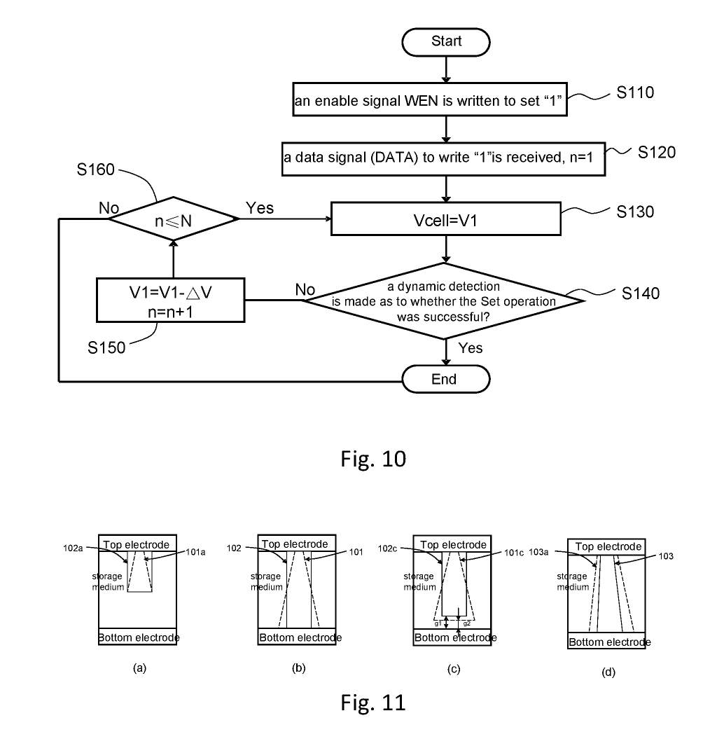

FIG. 10 is a schematic view of a method flowchart of a Set operation according to an embodiment of the invention. The method process of this Set operation will be described specifically below based on the Set operation signal in the embodiments shown in FIG. 10, FIG. 3 and FIG. 4.

Firstly, at step S110, an enable signal WEN is set as “1”, meaning that a writing operation circuit is prepared for starting a writing operation.

Next, at step S120, a data signal (DATA) to write DATA=1 is received, meaning that a Set operation is required to be performed now; meanwhile, n is set to be 1. At this moment, according to the DATA signal, the control logic module 330 enables the writing operation signal generation module 340 to generate a Set operation signal so as to apply excitation on the memory unit 370.

Next, at step S130, V_{cell}=V₁, that is, the voltage biased onto the memory unit 370 is set to be V₁. At this step, DATA=1 is simultaneously applied to the polarity selection module 350; and when DATA=1, the writing operation voltage V_{write} is applied to the memory unit 370 in the BL direction.

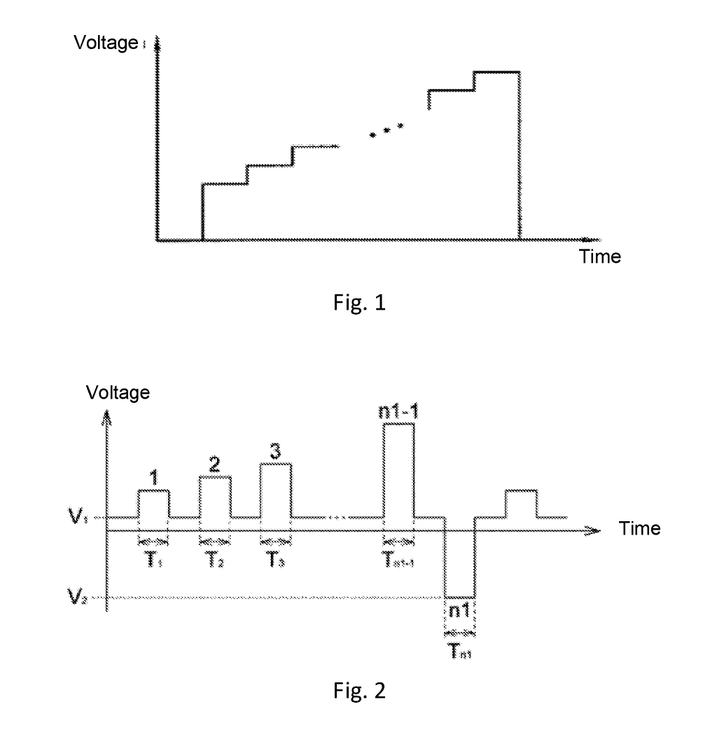

Next, at step S140, a dynamic detection is made as to whether the Set operation was successful. At this step, the I_{write} is monitored in real time by the dynamic current detection module 310. If I_{write} is larger than or equal to a certain preset threshold value, it means that a resistance conversion is realized at this moment. That is, a conversion point from high resistance state to low resistance state is found in real time. The dynamic current detection module 310 sends a FB signal 320 to the control logic module 330 so as to control the writing operation signal generation module 340 to terminate the Set operation signal, thus avoiding surplus write excitation signals after a successful Set operation. In this way, the CFs formed by the Set operation will no longer be affected by write excitation signals such as the Set operation signal, which is not only advantageous for improving the efficiency of writing operation (e.g., the speed of Set operation is increased by up to 54% as compared to the existing Set operation method shown in FIG. 1), but also is advantageous for reducing extra power consumption (e.g., the reduction of power consumption of Set operation is reduced by up to 34% as compared to the existing Set operation method shown in FIG. 1); meanwhile, a destructive influence on the storage performance by an over-writing operation can be also prevented. If it is determined that the Set operation was successful, the Set operation signal is terminated, and the Set operation process is finished directly.

Next, if it is determined that the Set operation was not successful, the method proceeds to step S150, V1=V1−ΔV, n=n+1. That is, the voltage of Set operation signal is further reduced. The specific magnitude of the amplitude ΔV of voltage reduction of the Set operation signal is not necessarily fixed and constant; rather, it can be selected within a certain range.

Next, at step S160, it is determined that whether n is smaller than or equal to N. At this step, the times of voltage reduction of the Set operation signal is restricted by limiting the magnitude of n, and a minimum voltage of the Set operation signal can be defined.

If it is determined that n is smaller than or equal to N, the process returns to step S130; and if it is determined that n is larger than N, the process is finished directly, meaning that the Set operation has failed.

Through a circulating operation of the above steps S130, S140, S150 and S160, a Set operation can be performed on a selected memory unit in the ReRAM by using electrical signal(s) hazing gradually-reducing voltages as shown in FIG. 4.

The applicant has performed Set operation tests on the same ReRAM chip by using the Set operation signal shown in FIG. 1 and the Reset operation signal shown in FIG. 4 respectively. A statistical analysis test result has shown that as compared to conventional Set operation signal(s) hazing gradually-increasing voltages, the Set operation signal(s) hazing gradually-reducing voltages according to the invention can improve storage performance at least from the following aspects: (1) the endurance of memory can be increased by at least two orders of magnitude; (2) the data retention of memory is also improved, wherein the failure rate of data retention in an on-state (Rₒₙ) is reduced by 88%, and the failure rate of data retention in an off-state (R_{off}) is reduced by 71%; (3) the window of R_{off}/Rₒₙ (i.e., high resistance/low resistance window) can be also increased to seven times.

Of course, it should be understood that different types of ReRAM chip test units and different other test conditions or the like may also result in different effects. That is, the extent to which the storage performances are improved in the above aspects may be different.

The applicant also found that by controlling the wave shapes of voltages of Set operation signals to excite the memory unit in a reduced form, the migration of oxygen vacancy for forming CFs in the storage medium can be controlled, so that the shapes of CFs can be controlled and performance improvements can be obtained in the above many aspects. Hereinafter, FIG. 11 illustratively reveals the formation of CFs and the reason why the storage performance of the ReRAM of the invention are improved.

FIG. 11 is a schematic view of the formation of conductive filaments in ReRAM, wherein FIG. 11(a) shows a schematic view before CFs are formed, FIG. 11(b) shows a schematic view of the shapes of CFs when the Set operation is finished, FIG. 11(c) shows a schematic view of the shapes of CFs when the Reset operation is finished, and FIG. 11(d) is a schematic view showing the influence that an over-writing operation has on CFS. In FIGS. 11(a) to 11(c), CFs shown by solid lines are formed based on the Set operation method shown in FIG. 10, and CFs shown by broken lines are formed based on the Set operation method shown in FIG. 1; and in FIG. 11(d), 103 illustrates CFs that are not affected by Over-Set operation, and 103a illustrates CFs that are affected by Over-Set operation.

As shown in FIG. 11(a), CFs are formed by movements of oxygen vacancy and oxygen ions under Set voltage. CF 101a, 101 and 101c shown by the broken lines mean that theses CFs are formed under a Set excitation which is a step-increasing voltages. When a first stage step voltage is applied to a ReRAM memory unit, the CFs begin to grow, and a passage resistance between upper and lower electrodes is reduced. In this situation, if the amplitude of the next stage Set voltage is increased, the current flowing through the passage between upper and lower electrodes is increased. Therefore, the intensify of electric field applied to the portions of CFs in the passage that have not yet been generated is increased. As a result, as compared to the last step, the thickness of filaments newly generated under this Set voltage step is increased relatively, and so on. In this way, by increasing the voltage in steps during the Set process, the finished CFs will have a conical shape that is substantially thin in the upper portion and thick in the lower portion, that is, CFs change from 101a to 101. CF 102a, 102 and 102c shown by the solid lines mean that theses CFs are formed under a Set excitation which is a step-reducing voltage. For example, using the Set operation method having step-reducing voltages shown in FIG. 10, after each stage of CF has grown, the voltage subsequently applied on the ReRAM memory unit is reduced. In this way, the current flowing through the passage between upper and lower electrodes can be controlled to be stable, and the final growth shape of CFs can be adjusted to be approximately a uniform column shape. The control over this shape of CFs has a direct influence on the improvements of performances such as endurance, data retention and high resistance/low resistance window R_{off}/Rₒₙ of the ReRAM, etc.

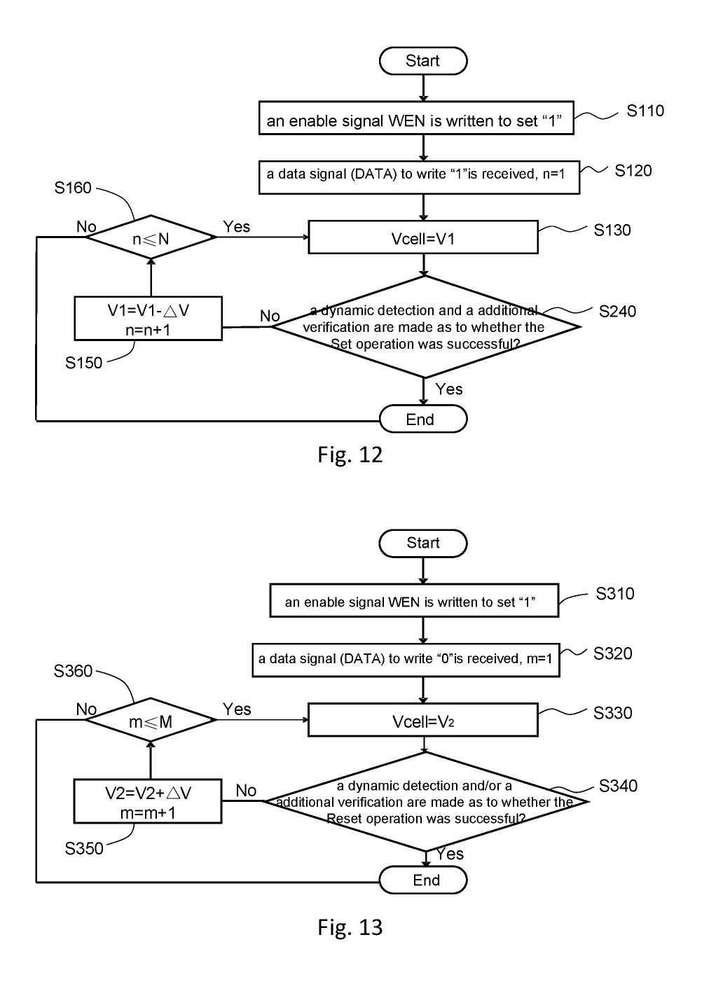

FIG. 12 is a schematic view of a method flowchart of a Set operation according to another embodiment of the invention. As compared to the Set operation method in the embodiment shown in FIG. 11, in the present embodiment, the main difference lies in that step S240 is different from step S140. As compared to step S140, step S240 is not limited to determining whether the Set operation was successful by dynamically detecting I_{write}. Step S240 further verifies whether the Set operation was successful using an additional verifying signal (the verifying signal 92 shown in FIG. 6). When both conditions are satisfied, it means that the Set operation was successful. Therefore, the embodiment shown in FIG. 12 is relatively suitable for being carried out based on the Set operation signal shown in FIG. 6.

It is noted that in the embodiment shown in FIG. 12, the termination of the Set operation signal is determined by dynamic detection, rather than being verified and determined by an additional verifying signal.

FIG. 13 is a schematic view of a method flowchart of a Reset operation according to an embodiment of the invention. The method process of this Reset operation will be described specifically below based on the Reset operation signal in the embodiments shown in FIG. 13, FIG. 3 and FIG. 7.

Firstly, at step S310, an enable signal WEN is written to set “1”, meaning that a writing operation circuit is prepared for starting a writing operation.

Next, at step S320, a data signal (DATA) to write DATA=0 is received, meaning that a Reset operation is required to be performed now; meanwhile, m is set to be 1. At this moment, according to the DATA signal, the control logic module 330 enables the writing operation signal generation module 340 to generate a Reset operation signal so as to apply excitation on the memory unit 370.

Next, at step S330, DATA=0 controls the polarity selection module 350 to apply a biased voltage onto the memory unit 370 in the SL direction so as to perform the Reset operation, V_{cell}=V₂.

Next, at step S340, a dynamic detection and/or an additional verification is made as to whether the Reset operation was successful. At this step, the I_{write} can be monitored in real time by the dynamic current detection module 310. If I_{write} is smaller than or equal to a certain preset threshold value, it means that a resistance conversion is realized at this moment. That is, a conversion point from low resistance state to high resistance state is found in real time; whether the Reset operation was successful can be also verified by a verifying signal output from the dynamic current detection module 310; of course, a successful Reset operation can be also determined only if both the above two conditions are satisfied simultaneously. When the Reset operation was successful, the dynamic current detection module 310 sends a FB signal 320 to the control logic module 330 so as to control the writing operation signal generation module 340 to terminate the Reset operation signal, thus avoiding surplus write excitation signals after a successful Reset operation.

Next, if it is determined that the Reset operation was not successful, the method proceeds to step S350, V2=V2+ΔV, m=m+1. That is, the voltage of Reset operation signal is further increased. The specific magnitude of the amplitude ΔV of voltage increase of the Reset operation signal is not necessarily fixed and constant; rather, it can be selected within a certain range.

Next, at step S360, it is determined that whether m is smaller than or equal to M. At this step, the times of voltage increase of the Reset operation signal is restricted by limiting the magnitude of m, and a maximum voltage of the Reset operation signal can be defined.

If it is determined that n is smaller than or equal to M, the process returns to step S330; and if it is determined that m is larger than M, the process is finished directly, meaning that the Reset operation has failed.

Through a circulating operation of the above steps S330, S340, S350 and S360, a Reset operation can be performed on a selected memory unit in the ReRAM by using electrical signals having gradually-increasing voltages as shown in FIG. 7.

It should be understood that the Set operation methods shown in FIGS. 10 and 12 can be respectively combined with the Reset operation method shown in FIG. 13 so as to perform a writing operation on the ReRAM.

It will be understood that when a component is referred to as being “connected” or “coupled” to another component, it can be directly connected or couple to said another component, or there can be an intervening component.

The above embodiments mainly describe a ReRAM and a writing operation method thereof for performing a Set operation using electrical signal(s) hazing step-reducing voltages according to the invention. While only some of the embodiments of the invention have been described, those skilled in the art will understand that the invention can be carried out in many other forms without departing from the spirit and scope thereof. Therefore, the illustrated examples and embodiments should be interpreted as schematic rather than limiting, and the invention can cover various modifications and replacements without departing form the spirit and scope of the invention defined by the appended claims.

1. A resistive random access memory, characterized by comprising:
a writing operation signal generation module which is at least used for generating electrical signal(s) hazing gradually reducing voltages as a set operation signal.

2. The resistive random access memory according to claim 1, wherein the electrical signal(s) hazing gradually reducing voltages are electrical signal(s) hazing step-reducing voltages.

3. The resistive random access memory according to claim 2, wherein the electrical signal(s) having step-reducing voltages are an electrical signal hazing continuously step-reducing voltages.

4. The resistive random access memory according to claim 2, wherein the electrical signal(s) hazing step-reducing voltages are step voltage pulse signals having step-reducing voltages.

5. The resistive random access memory according to claim 1, wherein the electrical signal(s) hazing gradually reducing voltages are an electrical signal hazing continuously gradually reducing voltages.

6. The resistive random access memory according to claim 1, wherein the resistive random access memory further comprises:
a dynamic current detection module which is at least used for dynamically detecting a current flowing through a memory unit of the resistive random access memory which is biased the set operation signal, so as to determine whether the Set operation was successful; and
a control logic module which is configured to receive a feedback signal from the dynamic current detection module in case that the dynamic current detection module determined the Set operation was successful, and based on the feedback signal, to enable the writing operation signal generation module to terminate generating the Set operation signal.

7. The resistive random access memory according to claim 6, wherein the resistive random access memory further comprises:
a polarity selection module for controlling the polarity that is biased on the memory unit by the Set operation signal and/or a Reset operation signal; and
a selection module for selecting a corresponding memory unit from a memory array of the resistive random access memory according to an address signal.

8. The resistive random access memory according to claim 1, wherein the writing operation signal generation module is further used for generating electrical signal(s) hazing gradually increasing voltages as a Reset operation signal.

9. The resistive random access memory according to claim 8, wherein the electrical signal(s) hazing gradually increasing voltages are step voltage pulse signal(s) hazing step-increasing voltages.

10. The resistive random access memory according to claim 1, wherein the writing operation signal generation module is further used for generating a verifying signal so as to verify whether the Set operation and/or Reset operation was successful.

11. A writing operation method for a resistive random access memory, characterized in that in a Set operation method of the writing operation method, electrical signal(s) hazing gradually reducing voltages is biased, as Set operation signals, onto a selected memory unit in the resistive random access memory.

12. The writing operation method according to claim 11, wherein the electrical signal(s) hazing gradually reducing voltages are electrical signal(s) hazing step-reducing voltages.

13. The writing operation method according to claim 12, wherein the electrical signal(s) hazing step-reducing voltages are an electrical signal hazing continuously step-reducing voltages.

14. The writing operation method according to claim 12, wherein the electrical signal(s) hazing step-reducing voltages are step voltage pulse signals having step-reducing voltages.

15. The writing operation method according to claim 11, wherein the electrical signal(s) hazing gradually reducing voltages are an electrical signal hazing continuously gradually reducing voltages.

16. The writing operation method according to claim 11, wherein the Set operation method further comprises:
dynamically detecting a current flowing through a memory unit of the resistive random access memory which is biased the set operation signal, so as to determine whether the Set operation was successful;
if it is determined that the set operation was successful, the Set operation signal is terminated; and if it is determined that the Set operation was not successful, the voltage of the Set operation signal will go on reducing.

17. The writing operation method according to claim 14, wherein when the electrical signal(s) hazing step-reducing voltages are step voltage pulse signals, after each time a voltage pulse excitation is applied, a verifying signal is biased so as to verify whether the Set operation was successful.

18. The writing operation method according to claim 11, wherein in a Reset operation method of the writing operation method, electrical signal(s) hazing gradually increasing voltages are biased, as a Reset operation signals, onto a selected memory unit in the resistive random access memory.

19. The writing operation method according to claim 18, wherein the electrical signal(s) hazing gradually increasing voltages are electrical signal(s) hazing step-increasing voltages.

20. The writing operation method according to claim 19, wherein the electrical signal(s) hazing step-increasing voltages are an electrical signal hazing continuously step-increasing voltages.

21. The writing operation method according to claim 19, wherein the electrical signal(s) hazing step-increasing voltages are step voltage pulse signals having step-increasing voltages.

22. The writing operation method according to claim 21, wherein after each time a voltage pulse excitation is applied, a verifying signal is biased so as to verify whether the Reset operation was successful.

23. The writing operation method according to claim 18, wherein the Reset operation method further comprises:
dynamically detecting a current flowing through a memory unit of the resistive random access memory which is biased the Reset operation signal, so as to determine whether the Reset operation was successful;
if it is determined that the Reset operation was successful, the Reset operation signal is terminated; and if it is determined that the Reset operation was not successful, the voltage of the Reset operation signal will go on increasing.

24. The resistive random access memory according to claim 9, wherein the writing operation signal generation module is further used for generating a verifying signal so as to verify whether the Set operation and/or Reset operation was successful.
